(19) United States
(12) Patent Application Publication
(10) Pub. No.: US 2026/0148939 A1
(43) Pub. Date: May 28, 2026

(54) ETCHING METHOD AND PLASMA PROCESSING APPARATUS

(71) Applicant: Tokyo Electron Limited, Tokyo (JP)

(72) Inventor: Takayuki KATSUNUMA, Miyagi (JP)

(73) Assignee: Tokyo Electron Limited, Tokyo (JP)

(21) Appl. No.: 19/453,537

(22) Filed: Jan. 20, 2026

Related U.S. Application Data
(63) Continuation of application No. PCT/JP2024/025936, filed on Jul. 19, 2024.

(30) Foreign Application Priority Data
Aug. 2, 2023 (JP) 2023-126149

(51) Int. Cl. H01J 37/32

(52) U.S. Cl. CPC H01J 37/3244; H01J 2237/334

(57) ABSTRACT

An etching method includes (a) providing a substrate on a substrate support in a chamber, the substrate including a first region and a second region, the first region including a first material including at least one selected from the group consisting of silicon oxide and carbon, and the second region including a second material different from the first material; and (b) exposing the substrate to first plasma generated from a first process gas including hydrogen fluoride without supplying electric bias to the substrate support.

### CROSS-REFERENCE TO RELATED APPLICATIONS

This application is a continuation application of PCT Application No. PCT/JP 2024/025936, filed on Jul. 19, 2024, which claims the benefit of priority from Japanese Patent Application No. 2023-126149, filed on Aug. 2, 2023. The entire contents of the above listed PCT and priority applications are incorporated herein by reference.

### BACKGROUND

### Field

Example embodiments of the present disclosure relate to an etching method and a plasma processing apparatus.

### Description of the Related Art

Japanese Unexamined Patent Publication No. 2019-12759 discloses a method for selectively etching a silicon nitride film. This method includes a first step of disposing a substrate having the silicon nitride film in a process space, a second step of introducing a gas including H and F into the process space, and a third step of selectively introducing a radical of an inert gas into the process space.

### SUMMARY

In one example embodiment, an etching method includes (a) providing a substrate on a substrate support in a chamber, the substrate including a first region and a second region, the first region including a first material including at least one selected from the group consisting of silicon oxide and carbon, and the second region including a second material different from the first material; and (b) exposing the substrate to first plasma generated from a first process gas including hydrogen fluoride without supplying electric bias to the substrate support.

### BRIEF DESCRIPTION OF THE DRAWINGS

FIG. 1 is a diagram for describing a configuration example of a plasma processing system.

FIG. 2 is a diagram for describing a configuration example of an inductively coupled plasma processing apparatus.

FIG. 3 is a flowchart illustrating an etching method according to an example embodiment.

FIG. 4 is a partially enlarged view of an example of a substrate to which the method in FIG. 3 may be applied.

FIG. 5 is a cross-sectional view illustrating a step of the etching method according to an example embodiment.

FIG. 6 is a cross-sectional view illustrating a step of the etching method according to an example embodiment.

FIG. 7 is a flowchart illustrating an etching method according to an example embodiment.

FIG. 8 is a graph illustrating an example of a relationship between a film type and an etching amount.

FIG. 9 is a partially enlarged view of an example of a substrate to which the method in FIG. 7 may be applied.

FIG. 10 is a cross-sectional view illustrating a step of the etching method according to an example embodiment.

FIG. 11 is a flowchart illustrating an etching method according to an example embodiment.

FIG. 12 is a partially enlarged view of an example of a substrate to which the method in FIG. 11 may be applied.

FIG. 13 is a cross-sectional view illustrating a step of the etching method according to an example embodiment.

FIG. 14 is a cross-sectional view illustrating a step of the etching method according to an example embodiment.

FIG. 15 is a cross-sectional view illustrating a step of the etching method according to an example embodiment.

FIG. 16 is a cross-sectional view illustrating a step of the etching method according to an example embodiment.

FIG. 17 is a flowchart illustrating an etching method according to an example embodiment.

FIG. 18 is a cross-sectional view illustrating a step of the etching method according to an example embodiment.

### DETAILED DESCRIPTION

Hereinafter, various example embodiments will be described in detail with reference to the drawings. In the drawing, the same or equivalent portions are denoted by the same reference signs.

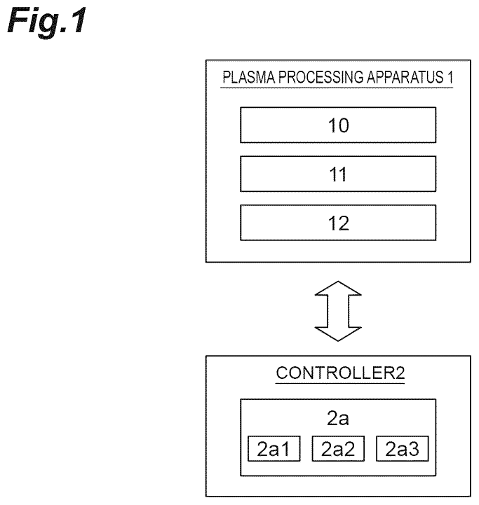

FIG. 1 illustrates an example configuration of a plasma processing system. In an embodiment, the plasma processing system includes a plasma processing apparatus 1 and a controller 2. The plasma processing system is an example substrate processing system, and the plasma processing apparatus 1 is an example substrate processing apparatus. The plasma processing apparatus 1 includes a plasma processing chamber 10, a substrate support 11, and a plasma generator 12. The plasma processing chamber 10 has a plasma processing space. The plasma processing chamber 10 further has at least one gas inlet for supplying at least one process gas into the plasma processing space and at least one gas outlet for exhausting gases from the plasma processing space. The gas inlet is connected to a gas supply 20 described below and the gas outlet is connected to a gas exhaust system 40 described below. The substrate support 11 is disposed in a plasma processing space and has a substrate supporting surface for supporting a substrate.

The plasma generator 12 is configured to generate a plasma from the at least one process gas supplied into the plasma processing space. The plasma formed in the plasma processing space may be, for example, a capacitively coupled plasma (CCP), an inductively coupled plasma (ICP), an electron-cyclotron-resonance (ECR) plasma, a helicon wave plasma (HWP), or a surface wave plasma (SWP). Various types of plasma generators may also be used, such as an alternating current (AC) plasma generator and a direct current (DC) plasma generator. In an embodiment, AC signal (AC power) used in the AC plasma generator has a frequency in a range of 100 kHz to 10 GHz. Hence, examples of the AC signal include a radio frequency (RF) signal and a microwave signal. In an embodiment, the RF signal has a frequency in a range of 100 kHz to 150 MHz.

The controller 2 processes computer executable instructions causing the plasma processing apparatus 1 to perform various steps described in this disclosure. The controller 2 may be configured to control individual components of the plasma processing apparatus 1 such that these components execute the various steps. In an embodiment, the functions of the controller 2 may be partially or entirely incorporated into the plasma processing apparatus 1. The controller 2 may include a processor 2a 1, a storage 2a2, and a communication interface 2a3. The controller 2 is implemented in, for example, a computer 2a. The processor 2a1 may be configured to read a program from the storage 2a2, and then perform various controlling operations by executing the program. This program may be preliminarily stored in the storage 2a2 or retrieved from any medium, as appropriate. The resulting program is stored in the storage 2a2, and then the processor 2a1 reads to execute the program from the storage 2a2. The medium may be of any type which can be accessed by the computer 2a or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or any combination thereof. The communication interface 2a3 can communicate with the plasma processing apparatus 1 via a communication line, such as a local area network (LAN).

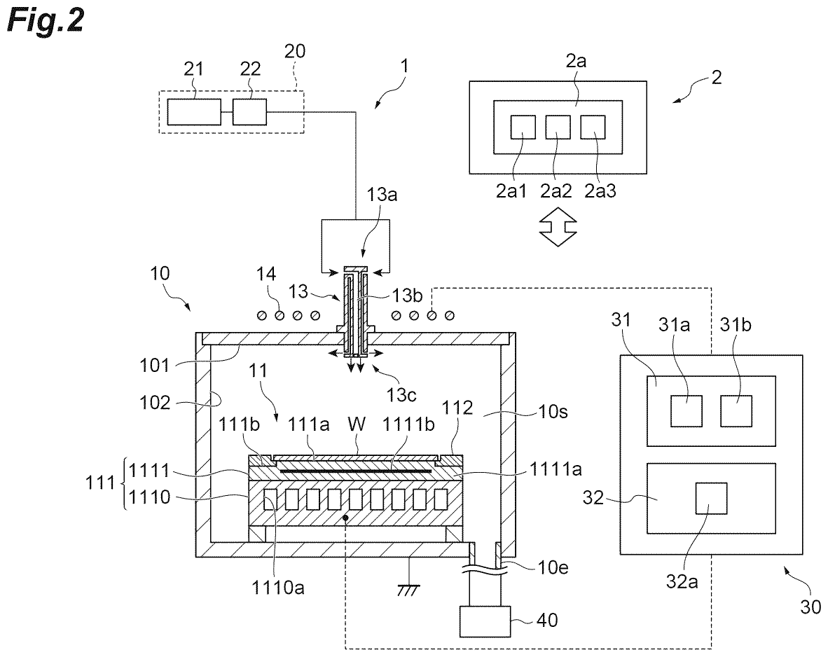

An example configuration of an inductively coupled plasma processing apparatus, which is an example of the plasma processing apparatus 1, will now be described. FIG. 2 illustrates the example configuration of the inductively coupled plasma processing apparatus.

The inductively coupled plasma processing apparatus 1 includes a plasma processing chamber 10, a gas supply 20, an electric power source 30, and a gas exhaust system 40. The plasma processing chamber 10 includes a dielectric window 101. The plasma processing apparatus 1 includes a substrate support 11, a gas introduction unit, and an antenna 14. The substrate support 11 is disposed in the plasma processing chamber 10. The antenna 14 is disposed on or above the plasma processing chamber 10 (i.e., on or above the dielectric window 101). The plasma processing chamber 10 has a plasma processing space 10s that is defined by the dielectric window 101, the sidewall 102 of the plasma processing chamber 10, and the substrate support 11. The plasma processing chamber 10 is grounded.

The substrate support 11 includes a body 111 and a ring assembly 112. The body 111 has a central region 111a for supporting a substrate W and an annular region 111b for supporting the ring assembly 112. An example of the substrate W is a wafer. The annular region 111b of the body 111 surrounds the central region 111a of the body 111 in plan view. The substrate W is disposed on the central region 111a of the body 111, and the ring assembly 112 is disposed on the annular region 111b of the body 111 so as to surround the substrate W on the central region 111a of the body 111. Thus, the central region 111a is also called a substrate supporting surface for supporting the substrate W, while the annular region 111b is also called a ring supporting surface for supporting the ring assembly 112.

In an embodiment, the body 111 includes a base 1110 and an electrostatic chuck 1111. The base 1110 includes a conductive member. The conductive member of the base 1110 can function as a bias electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In an embodiment, the ceramic member 1111a also has the annular region 111b. Any other member, such as an annular electrostatic chuck or an annular insulting member, surrounding the electrostatic chuck 1111 may have the annular region 111b. In this case, the ring assembly 112 may be disposed on either the annular electrostatic chuck or the annular insulating member, or both the annular electrostatic chuck 1111 and the annular insulating member. At least one RF/DC electrode coupled to a radio frequency (RF) source 31 and/or a direct current (DC) source 32 described below may be disposed in the ceramic member 1111a. In this case, the at least one RF/DC electrode functions as the bias electrode. It is noted that the conductive member of the base 1110 and the at least one RF/DC electrode may each function as a bias electrode. The electrostatic electrode 1111b may also be function as a bias electrode. The substrate support 11 accordingly includes at least one bias electrode.

The ring assembly 112 includes one or more annular members. In an embodiment, the annular members include one or more edge rings and at least one cover ring. The edge ring is composed of a conductive or insulating material, whereas the cover ring is composed of an insulating material.

The substrate support 11 may also include a temperature adjusting module that is configured to adjust at least one of the electrostatic chuck 1111, the ring assembly 112, and the substrate to a target temperature. The temperature adjusting module may be a heater, a heat transfer medium, a flow passage 1110a, or any combination thereof. A heat transfer fluid, such as brine or gas, flows into the flow passage 1110a. In an embodiment, the flow passage 1110a is formed in the base 1110, one or more heaters are disposed in the ceramic member 1111a of the electrostatic chuck 1111. The substrate support 11 may further include a heat transfer gas supply configured to supply a heat transfer gas to a gap between the rear surface of the substrate W and the central region 111a.

The gas introduction unit is configured to introduce the at least one process gas from the gas supply 20 into the plasma processing space 10s. In an embodiment, the gas introduction unit includes a center gas injector (CGI) 13. The CGI 13 is disposed above the substrate support 11 and attached to a central opening formed in the dielectric window 101. The CGI 13 has at least one gas inlet 13a, at least one gas flow passage 13b, and at least one gas introduction port 13c. The process gas supplied to the gas inlet 13a flows through the gas flow passage 13b and is then introduced into the plasma processing space 10s from the gas introduction port 13c. The gas introduction unit may include one or more side gas injectors (SGIs) attached to one or more openings formed in the sidewall 102, in addition to or in place of the CGI 13.

The gas supply 20 may include at least one gas source 21 and at least one flow controller 22. In an embodiment, the gas supply 20 is configured to supply at least one process gas from the corresponding gas source 21 through the corresponding flow controller 22, into the gas introduction unit. Each flow controller 22 may be, for example, a mass flow controller or pressure-controlled flow controller. The gas supply 20 may include one or more flow modulation devices that can modulate or pulse the flow of the at least one process gas.

The electric power source 30 include an RF source 31 coupled to the plasma processing chamber 10 through at least one impedance matching circuit. The RF source 31 is configured to supply at least one RF signal (RF power) to at least one bias electrode and/or the antenna 14. A plasma is thereby formed from at least one process gas supplied into the plasma processing space 10s. Thus, the RF source 31 can function as at least part of the plasma generator 12. The bias RF signal supplied to the at least one bias electrode causes a bias potential to occur in the substrate W, which potential then attracts ionic components in the plasma to the substrate W.

In an embodiment, the RF source 31 includes a first RF generator 31a and a second RF generator 31b. The first RF generator 31a is coupled to the antenna 14 through the at least one impedance matching circuit and is configured to generate a source RF signal (source RF power) for generating a plasma. In an embodiment, the source RF signal has a frequency in a range of 10 MHz to 150 MHz. In an embodiment, the first RF generator 31a may be configured to generate two or more source RF signals having different frequencies. The resulting source RF signal(s) is supplied to the antenna 14.

The second RF generator 31b is coupled to the at least one lower electrode through the at least one impedance matching circuit and is configured to generate a bias RF signal (bias RF power). The bias RF signal and the source RF signal may have the same frequency or different frequencies. In an embodiment, the bias RF signal has a frequency which is less than that of the source RF signal. In an embodiment, the bias RF signal has a frequency in a range of 100 kHz to 60 MHz. In an embodiment, the second RF generator 31b may be configured to generate two or more bias RF signals having different frequencies. The resulting bias RF signal(s) is supplied to the at least one lower electrode. In various embodiments, at least one of the source RF signal and the bias RF signal may be pulsated.

The electric power source 30 may also include a DC source 32 coupled to the plasma processing chamber 10. The DC source 32 includes a bias DC generator 32a. In an embodiment, the bias DC generator 32a is connected to at least one bias electrode and is configured to generate a bias DC signal. The resulting bias DC signal is applied to the at least one bias electrode.

In various embodiments, the bias DC signal may be a pulsed. In this case, a sequence of voltage pulses is applied to the at least one bias electrode. The voltage pulses have rectangular, trapezoidal, or triangular waveform, or a combined waveform thereof. In an embodiment, a waveform generator for generating a sequence of voltage pulses from the DC signal is disposed between the bias DC generator 32a and the at least one bias electrode. The bias DC generator 32a and the waveform generator thereby functions as a voltage pulse generator. The voltage pulse may have positive polarity or negative polarity. A sequence of voltage pulses may also include one or more positive voltage pulses and one or more negative voltage pulses in a cycle. The bias DC generator 32a may be disposed in addition to the RF power source 31, or the bias DC generator 32a may be disposed in place of the second RF generator 31b.

The antenna 14 includes one or more coils. In an embodiment, the antenna 14 may include an outer coil and an inner coil that are coaxially disposed. In this case, the RF source 31 may be connected to both the outer coil and the inner coil, or either the outer coil or the inner coil. In the former case, a single RF generator may be connected to the outer and inner coils, or different RF generators may be connected to the outer and inner coils, respectively.

The gas exhaust system 40 may be connected to, for example, the gas outlet 10e provided in the bottom wall of the plasma processing chamber 10. The gas exhaust system 40 may include a pressure regulation valve and a vacuum pump. The pressure regulation valve enables the pressure in the plasma processing space 10s to be adjusted. The vacuum pump may be a turbo-molecular pump, a dry pump, or a combination thereof.

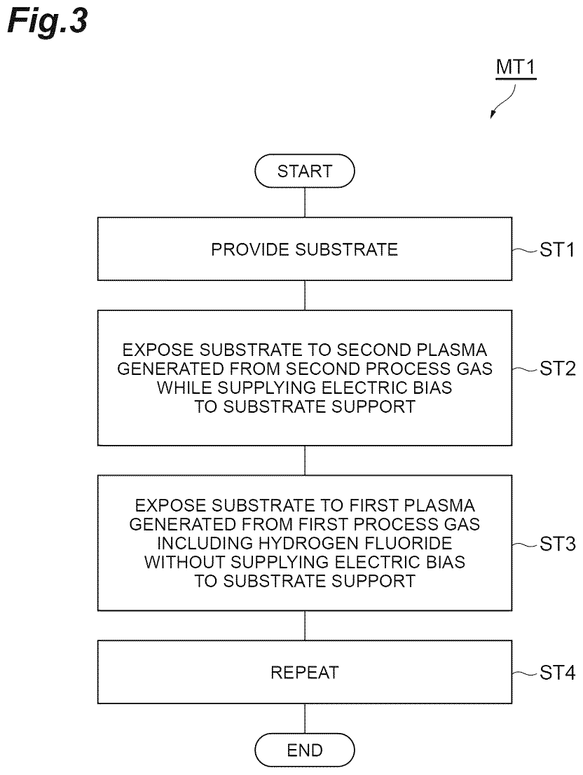

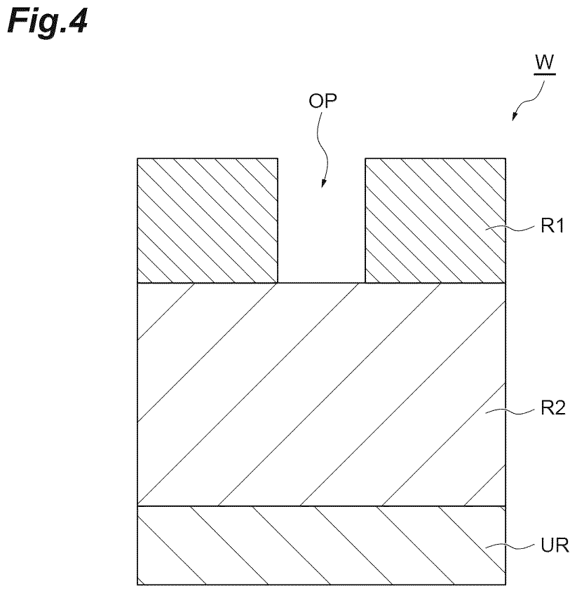

FIG. 3 is a flowchart illustrating an etching method according to an example embodiment. The etching method MT1 illustrated in FIG. 3 (hereinafter, referred to as “method MT1”) may be performed by a plasma processing apparatus 1 of the above-described embodiment. The method MT1 may be applied to the substrate W in FIG. 4.

FIG. 4 is a cross-sectional view of an example of a substrate to which the method in FIG. 3 may be applied. As illustrated in FIG. 4, in one embodiment, the substrate W may include a first region R1 and a second region R2. The first region R1 may be a mask. The first region R1 may have at least one opening OP. At least one opening OP may be a hole or a slit. The first region R1 may have a plurality of openings OP. The first region R1 may be a region on the second region R2. The second region R2 may be an etching target film. The substrate W may further include an underlying region UR. The second region R2 may be a region on the underlying region UR. The first region R1, the second region R2, and the underlying region UR may be arranged in this order. Each of the first region R1, the second region R2, and the underlying region UR may be a film.

The first region R1 includes a first material. The first material may include at least one selected from the group consisting of silicon oxide (SiOₓ) and carbon. x is a positive real number. The first material may be a carbon-containing material other than a carbon fluoride. The first material may be at least one carbon-containing material selected from the group consisting of a photoresist (polymer) and amorphous carbon.

The second region R2 includes a second material. The second material is different from the first material. The second material may include at least one selected from the group consisting of silicon oxide, silicon nitride (SiNₓ), silicon oxynitride (SiON), polysilicon, a metal, and carbon. x is a positive real number. The second material may include at least one metal selected from the group consisting of tungsten (W), molybdenum (Mo), and titanium (Ti). The second material may be a compound including a metal element and a non-metal element. The second material may be at least one selected from the group consisting of a metal silicide, a metal nitride, and a metal carbide. The second material may be tungsten silicide (WSi). The second material may be a carbon fluoride.

The underlying region UR may include a metal or silicon.

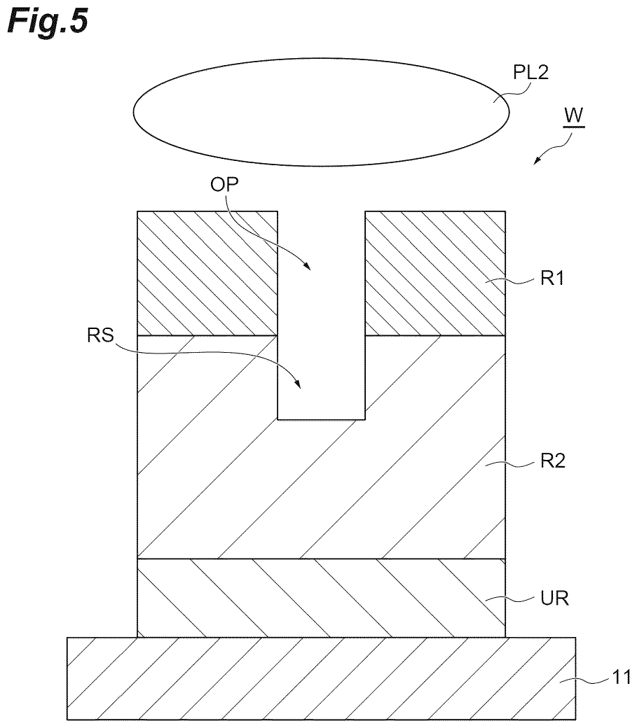

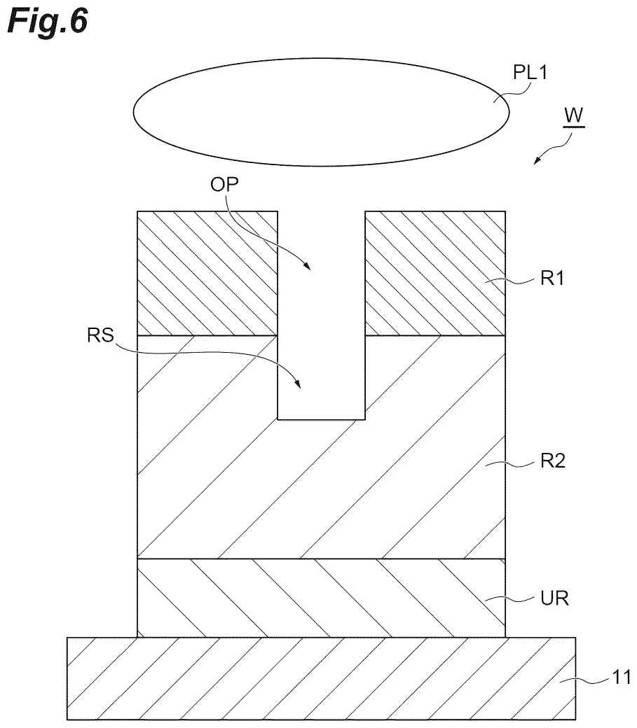

In the following, the method MT1 will be described with reference to FIGS. 3 to 6 by using, as an example, the case where the method MT1 is applied to the substrate W by using the plasma processing apparatus 1 in the above-described embodiment. FIGS. 5 and 6 are cross-sectional views illustrating a step of the etching method according to an example embodiment. In a case where a plasma processing apparatus 1 is used, the method MT1 may be performed in the plasma processing apparatus 1 in a manner that a controller 2 controls each unit of the plasma processing apparatus 1. In the method MT1, as illustrated in FIG. 2, the substrate W on a substrate support 11 disposed in a plasma processing chamber 10 is processed.

As illustrated in FIG. 3, the method MT1 may include Step ST1 to Step ST4. Step ST1 to Step ST4 may be executed in order. Step ST2 may be performed after Step ST3. The method MT1 may not include at least one of Step ST2 and Step ST4.

### Step ST1

In Step ST1, the substrate W illustrated in FIG. 4 is provided on the substrate support 11 in the plasma processing chamber 10.

### Step ST2

In Step ST2, as illustrated in FIG. 5, the substrate W is exposed to second plasma PL2 generated from a second process gas while supplying electric bias to the substrate support 11. Accordingly, the second region R2 is etched. A recess RS is formed in the second region R2 by etching. The recess RS corresponds to the opening OP of the first region R1. The electric bias supplied to the substrate support 11 may be bias RF power or bias DC power. The supply of the second process gas may be stopped at the end of Step ST2.

The second process gas may include a fluorocarbon gas. Examples of the fluorocarbon gas include C₄F₆ gas. The second process gas may further contain an oxygen-containing gas. Examples of the oxygen-containing gas include oxygen gas. The second process gas may further include at least one inert gas selected from the group consisting of a noble gas and nitrogen (N₂) gas. In the present specification, examples of the noble gas include argon (Ar) gas, helium (He) gas, xenon (Xe) gas, and neon (Ne) gas.

The duration of Step ST2 may be 0.1 to 100 seconds or 10 to 50 seconds.

In Step ST2, a temperature of the substrate support 11 may be 10° C. or higher, 30° C. or higher, or 40° C. or higher. In Step ST2, a temperature of the substrate support 11 may be 150° C. or lower, 120° C. or lower, or 80° C. or lower.

In Step ST2, the pressure in the plasma processing chamber 10 may be 10 mTorr (1.3 Pa) or more. In addition, the pressure in the plasma processing chamber 10 may be 100 mTorr (13 Pa) or less.

Step ST2 may be performed as follows. The second process gas is supplied into the plasma processing chamber 10 by the gas supply 20. The controller 2 controls the gas supply 20 and the plasma generator 12 such that the second plasma PL2 is generated from the second process gas. The controller 2 controls the electric power source 30 such that the electric bias is supplied to the substrate support 11.

### Step ST3

In Step ST3, as illustrated in FIG. 6, the substrate W is exposed to first plasma PL1 generated from a first process gas without supplying the electric bias to the substrate support 11. The radio frequency power may not be supplied to the substrate support 11. The recess RS may be etched by the first plasma PL1. The deposit adhering to the opening OP in Step ST2 may be removed by the first plasma PL1. The etching residues in Step ST2 may be removed by the first plasma PL1. The supply of the first process gas may be stopped at the end of Step ST3.

The first process gas is different from the second process gas. The first process gas includes hydrogen fluoride gas. The first process gas may further include at least one inert gas selected from the group consisting of a noble gas and nitrogen gas. A flow rate of the hydrogen fluoride gas may be the largest among the flow rates of all the gases included in the first process gas. The inert gas which may be included in the first process gas may be the same as or different from the inert gas included in the second process gas in Step ST2. The first process gas may not include a fluorine-containing gas other than hydrogen fluoride gas.

The duration of Step ST3 may be shorter than the duration of Step ST2. The duration of Step ST3 may be 0.1 to 100 seconds or 1 to 5 seconds.

In Step ST3, a temperature of the substrate support 11 may be 10° C. or higher, 30° C. or higher, or 50° C. or higher. In Step ST3, a temperature of the substrate support 11 may be 150° C. or lower or 120° C. or lower.

The pressure in the plasma processing chamber 10 in Step ST3 may be higher than the pressure in the plasma processing chamber 10 in Step ST2. In Step ST3, the pressure in the plasma processing chamber 10 may be 10 mTorr (1.3 Pa) or more. In addition, the pressure in the plasma processing chamber 10 may be 1000 mTorr (130 Pa) or less.

Step ST3 may be performed as follows. The first process gas is supplied into the plasma processing chamber 10 by the gas supply 20. The controller 2 controls the gas supply 20 and the plasma generator 12 such that the first plasma PL1 is generated from the first process gas. The controller 2 controls the electric power source 30 such that the electric bias is not supplied to the substrate support 11.

### Step ST4

In Step ST4, Step ST2 and Step ST3 are repeated. As a result, the etching amount of the second region R2 can be increased, and thus the recess RS can be deepened.

According to the method MT1, the etching of the first region R1 is suppressed in Step ST3 as compared with a case where the electric bias is supplied to the substrate support 11. As a result, an etching selectivity of the second region R2 to the first region R1 can be improved.

In addition, in the method MT1, the deposit (for example, the deposit including carbon fluoride) adhered to the opening OP in Step ST2 can be removed in Step ST3. Therefore, it is possible to prevent the clogging of the opening OP due to the deposit. Further, the flow rate of the gas (for example, an oxygen-containing gas) for preventing the clogging included in the second process gas in Step ST2 can be reduced.

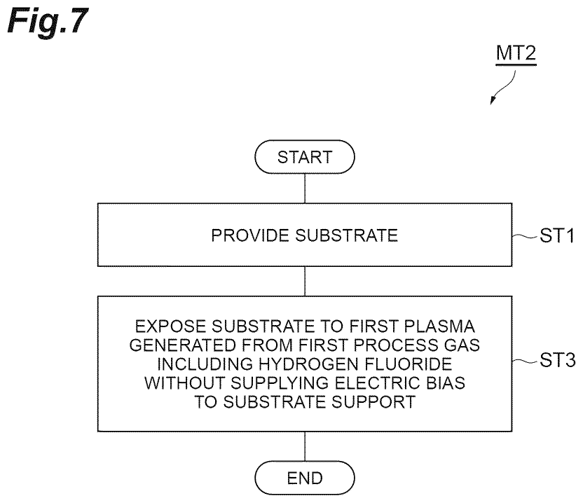

FIG. 7 is a flowchart illustrating an etching method according to an example embodiment. The etching method MT2 illustrated in FIG. 7 (hereinafter, referred to as “method MT2”) may be performed by the plasma processing apparatus 1 of the above-described embodiment. The method MT2 may be applied to the substrate W in FIG. 4.

In the following, the method MT2 will be described with reference to FIGS. 4, 6, and 7 by using, as an example, the case where the method MT2 is applied to the substrate W by using the plasma processing apparatus 1 in the above-described embodiment. In a case where the plasma processing apparatus 1 is used, the method MT2 may be performed in the plasma processing apparatus 1 in a manner that the controller 2 controls each unit of the plasma processing apparatus 1. In the method MT2, as illustrated in FIG. 2, the substrate W on a substrate support 11 disposed in a plasma processing chamber 10 is processed.

As illustrated in FIG. 7, the method MT2 may include Step ST1 and Step ST3. Step ST1 and Step ST3 may be executed in order.

### Step ST1

In Step ST1, the substrate W illustrated in FIG. 4 is provided on the substrate support 11 in the plasma processing chamber 10. In the present embodiment, the second material included in the second region R2 may include at least one selected from the group consisting of silicon nitride, silicon oxynitride, polysilicon, and a metal.

### Step ST3

In Step ST3, as illustrated in FIG. 6, the substrate W is exposed to the first plasma PL1 generated from the first process gas including hydrogen fluoride gas without supplying the electric bias to the substrate support 11. Accordingly, the second region R2 is etched. A recess RS is formed in the second region R2 by etching. The supply of the first process gas may be stopped at the end of Step ST3.

According to the method MT2, the etching of the first region R1 is suppressed in Step ST3 as compared with a case where the electric bias is supplied to the substrate support 11. As a result, an etching selectivity of the second region R2 to the first region R1 can be improved.

Various experiments performed for evaluating the method MT1 and the method MT2 are described below. The experiments described below do not limit the present disclosure.

### First Experiment

In a first experiment, first, a substrate is provided on a substrate support in a chamber of the plasma processing apparatus (Step ST1). The substrate has a silicon oxide film and a mask on the silicon oxide film. The mask includes amorphous carbon.

Next, the silicon oxide film is etched through an opening of the mask by second plasma generated from the second process gas while supplying the electric bias to the substrate support (Step ST2). The second process gas is a mixed gas of a fluorocarbon gas, Ar gas, and oxygen gas. A temperature of the substrate support in Step ST2 is 50° C. The duration of Step ST2 is 30 seconds.

Next, the substrate is exposed to the first plasma generated from the first process gas without supplying the electric bias to the substrate support (Step ST3). The first process gas is a mixed gas of HF gas and Ar gas. A temperature of the substrate support in Step ST3 is 60° C. The duration of Step ST3 is 2 seconds. Next, Step ST2 and Step ST3 are repeated such that the number of times (the number of cycles) of execution of each of Step ST2 and Step ST3 is 10 (Step ST4).

### Second Experiment

A second experiment is performed in the same manner as in the first experiment, except that Step ST4 is performed such that the duration of Step ST2 is 25 seconds and the number of cycles is 12.

### Third Experiment

A third experiment is performed in the same manner as in the first experiment, except that Step ST4 is performed such that the duration of Step ST2 is 20 seconds and the number of cycles is 15.

### Fourth Experiment

A fourth experiment is performed in the same manner as in the first experiment, except that the duration of Step ST2 is 300 seconds and Step ST3 and Step ST4 are not performed.

### First Experimental Results

In each of the first experiment to the fourth experiment, the cross section of the substrate is observed. The etching amount of the mask and the etching amount of the silicon oxide film are measured, and an etching selectivity of the silicon oxide film with respect to the mask is calculated. An etching selectivity in the first experiment is 5.82. An etching selectivity of the second experiment is 5.63. An etching selectivity in the third experiment is 5.49. An etching selectivity in the fourth experiment is 4.84. Therefore, it is found that the etching selectivity is improved by performing Step ST3.

Further, in each of the first experiment to the fourth experiment, the surface of the substrate is observed. In the fourth experiment, clogging of the opening of the mask is observed. In the first experiment to the third experiment, the occurrence of clogging is prevented as compared with the fourth experiment. Therefore, it is found that performing Step ST3 can prevent the occurrence of clogging.

### Fifth Experiment

In a fifth experiment, first, a substrate is provided on a substrate support in a chamber of the plasma processing apparatus (Step ST1). The substrate has a SiO₂ film on the surface.

Next, the substrate is exposed to plasma generated from a process gas without supplying the electric bias to the substrate support (Step ST3). The process gas is a mixed gas of HF gas and Ar gas. A temperature of the substrate support in Step ST3 is 60° C. The duration of Step ST3 is 300 seconds.

### Sixth Experiment

A sixth experiment is performed in the same manner as in the fifth experiment, except that a substrate having a SiN film on a surface is used.

### Seventh Experiment

A seventh experiment is performed in the same manner as in the fifth experiment, except that a substrate having a photoresist film on a surface is used.

### Eighth Experiment

An eighth experiment is performed in the same manner as in the fifth experiment, except that a substrate having a polysilicon film on a surface is used.

### Ninth Experiment

A ninth experiment is performed in the same manner as in the fifth experiment, except that a substrate having a WSi film on a surface is used.

### Tenth Experiment

A tenth experiment is performed in the same manner as in the fifth experiment, except that a substrate having a carbon fluoride film on a surface is used.

### Second Experimental Results

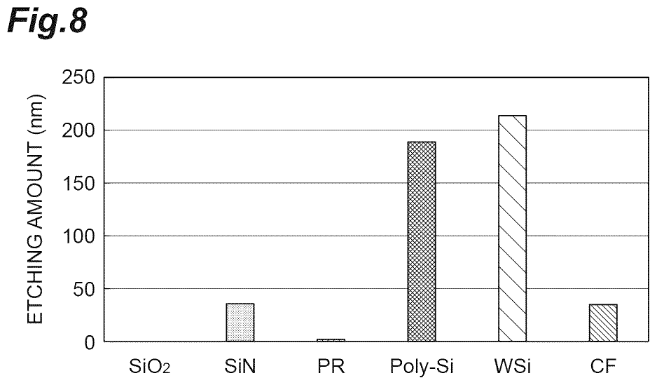

In each of the fifth experiment to the tenth experiment, the etching amount of the film included in the substrate is measured. The results are illustrated in FIG. 8. As illustrated in FIG. 8, it is found that the WSi film, the polysilicon (Poly-Si) film, the SiN film, and the carbon fluoride (CF) film are easily etched in this order. It is also found that the SiO₂ film and the photoresist (PR) film are hardly etched. The reason why the SiO₂ film is less likely to be etched than the SiN film is considered as follows, but the reason is not limited thereto. The activation energy of the reaction between SiO₂ and HF is very large as compared with the activation energy of the reaction between SiN and HF. In addition, the generation energy of the reaction between SiO₂ and HF is also large as compared with the generation energy of the reaction between SiN and HF.

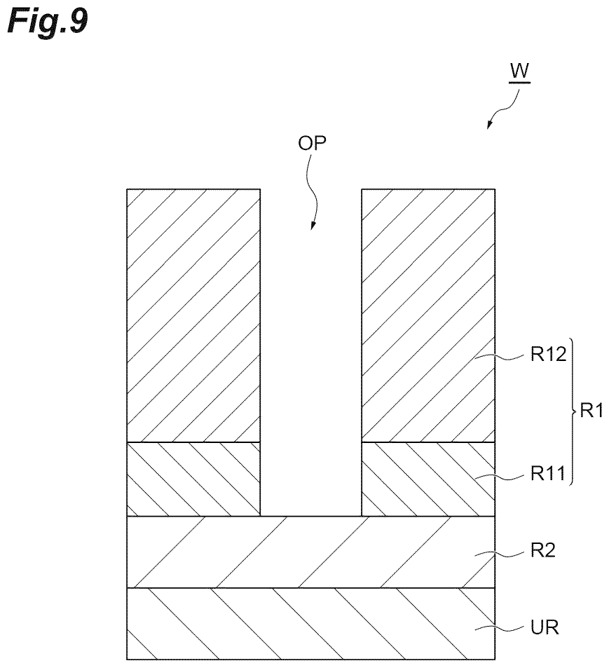

FIG. 9 is a cross-sectional view of an example of a substrate to which the method in FIG. 7 may be applied. As illustrated in FIG. 9, the first region R1 of the substrate W in the present embodiment includes a first portion R11 and a second portion R12. The first portion R11 is disposed between the second region R2 and the second portion R12. Each of the underlying region UR and the first portion R11 may include silicon oxide. The second region R2 may include a metal. The second portion R12 may include carbon such as spin-on carbon (SOC).

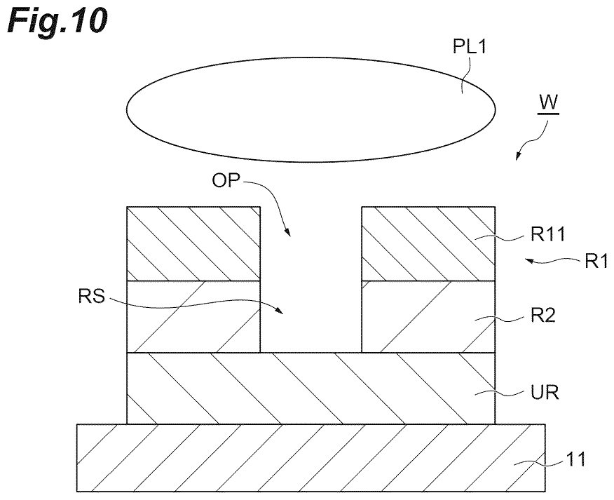

In the following, a case where the method MT2 of FIG. 7 is applied to the substrate W of FIG. 9 by using the plasma processing apparatus 1 in the above-described embodiment will be described with reference to FIGS. 9 and 10. FIG. 10 is a cross-sectional view illustrating a step of the etching method according to an example embodiment.

### Step ST1

In Step ST1, the substrate W illustrated in FIG. 9 is provided on the substrate support 11 in the plasma processing chamber 10. The opening OP of the first region R1 may be formed by etching.

### Step ST3

In Step ST3, as illustrated in FIG. 10, the substrate W is exposed to the first plasma PL1 generated from the first process gas including hydrogen fluoride gas without supplying the electric bias to the substrate support 11. Accordingly, the second region R2 is etched. A recess RS is formed in the second region R2 by etching. The underlying region UR may function as an etching stop layer. In Step ST3, the second portion R12 may be removed, but the first portion R11 is difficult to etch.

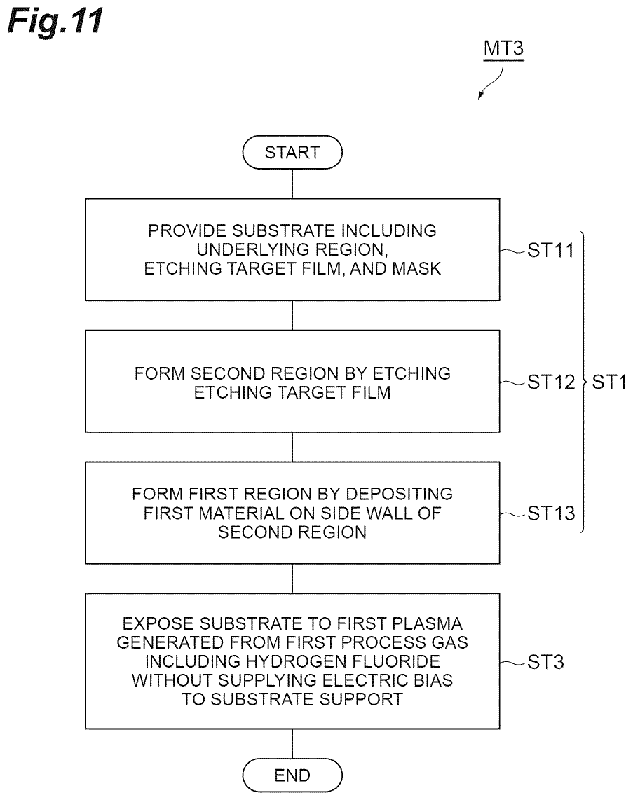

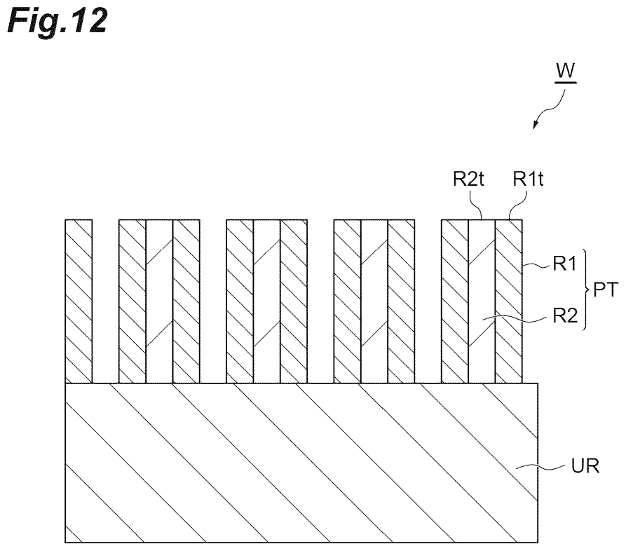

FIG. 11 is a flowchart illustrating an etching method according to an example embodiment. The etching method MT3 illustrated in FIG. 11 (hereinafter, referred to as “method MT3”) may be performed by the plasma processing apparatus 1 of the above-described embodiment. The method MT3 may be applied to the substrate W of FIG. 12.

FIG. 12 is a cross-sectional view of an example of a substrate to which the method in FIG. 11 may be applied. As illustrated in FIG. 12, in one embodiment, the substrate W further includes an underlying region UR in addition to the first region R1 and the second region R2. The first region R1 and the second region R2 are regions on the underlying region UR. At least a top R1t of the first region R1 is exposed. At least a top R2t of the second region R2 is exposed. The second region R2 is adjacent to the first region R1. The second region R2 may be disposed between a pair of first regions R1. The pair of the first regions R1 and the second region R2 may constitute a protrusion PT. A plurality of protrusions PT may be arranged separately from each other on the underlying region UR.

The first region R1 may include at least one selected from the group consisting of silicon oxide and carbon. The second region R2 may include at least one selected from the group consisting of silicon nitride, polysilicon, carbon fluoride, and a metal. The metal that may be included in the second region R2 may include at least one selected from the group consisting of tungsten, molybdenum, niobium (Nb), tantalum (Ta), and titanium. The tungsten that may be included in the second region R2 may include at least one selected from the group consisting of WSiₓ, WCₓ, WNₓ, WCₓN_{y}, WSiₓN_{y}, and WOₓ. x and y are positive real numbers.

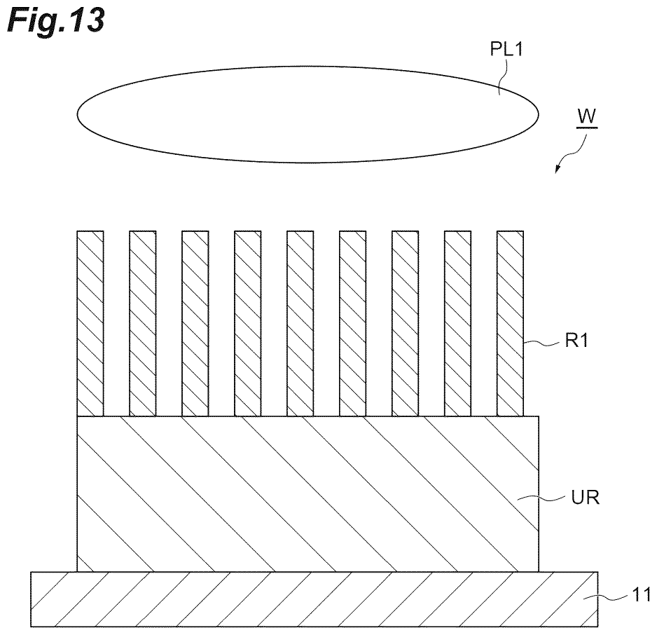

In the following, the method MT3 will be described with reference to FIGS. 11 to 16 by using, as an example, the case where the method MT3 is applied to the substrate W of FIG. 12 by using the plasma processing apparatus 1 in the above-described embodiment. FIGS. 13 to 16 are cross-sectional views illustrating a step of the etching method according to an example embodiment. In a case where the plasma processing apparatus 1 is used, the method MT3 may be performed in the plasma processing apparatus 1 in a manner that the controller 2 controls each unit of the plasma processing apparatus 1. In the method MT3, as illustrated in FIG. 2, the substrate W on a substrate support 11 disposed in a plasma processing chamber 10 is processed.

As illustrated in FIG. 11, the method MT3 may include Step ST1 and Step ST3. Step ST1 and Step ST3 may be executed in order. Step ST1 may include Step ST11 to Step ST13. Step ST11 to Step ST13 may be executed in order.

### Step ST1

In Step ST1, the substrate W illustrated in FIG. 12 is provided on the substrate support 11 in the plasma processing chamber 10.

### Step ST3

In Step ST3, as illustrated in FIG. 13, the substrate W is exposed to the first plasma PL1 generated from the first process gas including hydrogen fluoride gas without supplying the electric bias to the substrate support 11. Accordingly, the second region R2 is etched. The second region R2 is selectively etched with respect to the first region R1. The second region R2 is removed by etching. As a result, a plurality of first regions R1 are arranged separately from each other on the underlying region UR. The supply of the first process gas may be stopped at the end of Step ST3.

According to the method MT3, the etching of the first region R1 is suppressed in Step ST3 as compared with a case where the electric bias is supplied to the substrate support 11. As a result, an etching selectivity of the second region R2 to the first region R1 can be improved.

In a case where Step ST1 includes Steps ST11 to ST13, the substrate W of FIG. 12 is provided as follows.

### Step ST11

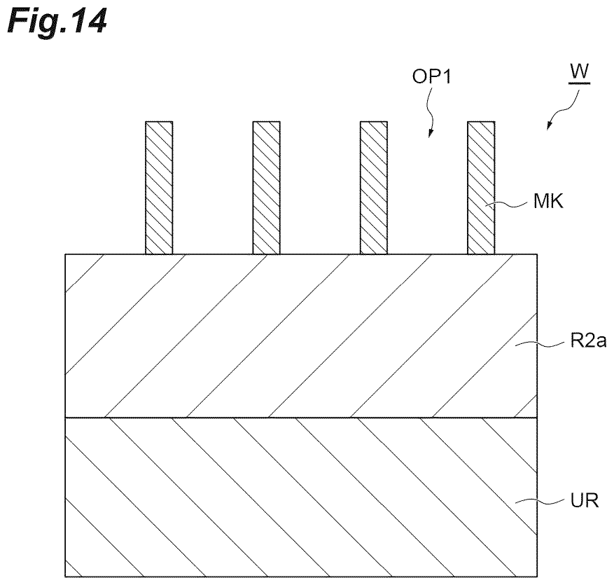

In Step ST11, a substrate W of FIG. 14 is provided. The substrate W includes the underlying region UR, an etching target film R2a on the underlying region UR, and a mask MK on the etching target film R2a. The etching target film R2a includes the second material included in the second region R2. The mask MK includes at least one opening OP1. The mask MK may include carbon such as amorphous carbon or spin-on carbon (SOC).

### Step ST12

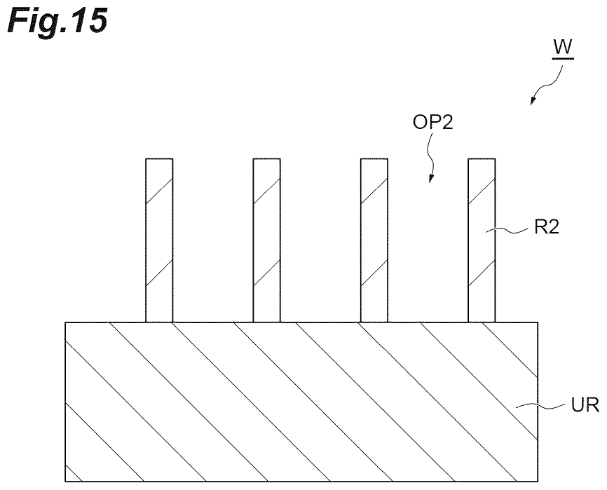

In Step ST12, as illustrated in FIG. 15, the second region R2 is formed by etching the etching target film R2a through the opening OP1 of the mask MK. The second region R2 has an opening OP2 corresponding to the opening OP1. After the opening OP2 is formed, the mask MK may be removed.

### Step ST13

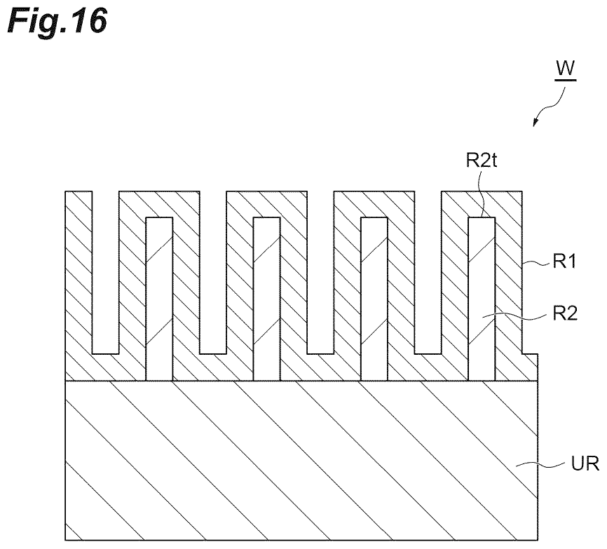

In Step ST13, as illustrated in FIG. 16, the first region R1 is formed by depositing the first material on a side wall of the second region R2. After deposition, the top R2t of the second region R2 and the underlying region UR may be exposed by removing a part of the first region R1 through etching. In this way, the substrate W of FIG. 12 is provided.

The first material can be deposited on the side wall of the second region R2 by a method such as ALD or MLD. In a case where the first material is deposited by ALD, the substrate W is exposed to a process gas including a silicon-containing precursor (aminosilane, SiCl₄, SiF₄, or the like). Accordingly, a precursor layer is formed on a surface of the second region R2. Thereafter, the substrate W is exposed to plasma generated from a process gas including an oxygen-containing gas (O₂, CO, CO₂, or the like). Accordingly, the precursor layer is modified to form a silicon oxide film. In a case where the first material is deposited by MLD, the substrate W is exposed to a first process gas including a first organic compound. In this manner, an adsorption layer in which the first organic compound is adsorbed is formed on the surface of the second region R2. Thereafter, the substrate W is exposed to a second process gas including a second organic compound different from the first organic compound. In this manner, an organic film is formed by the reaction between the first organic compound and the second organic compound.

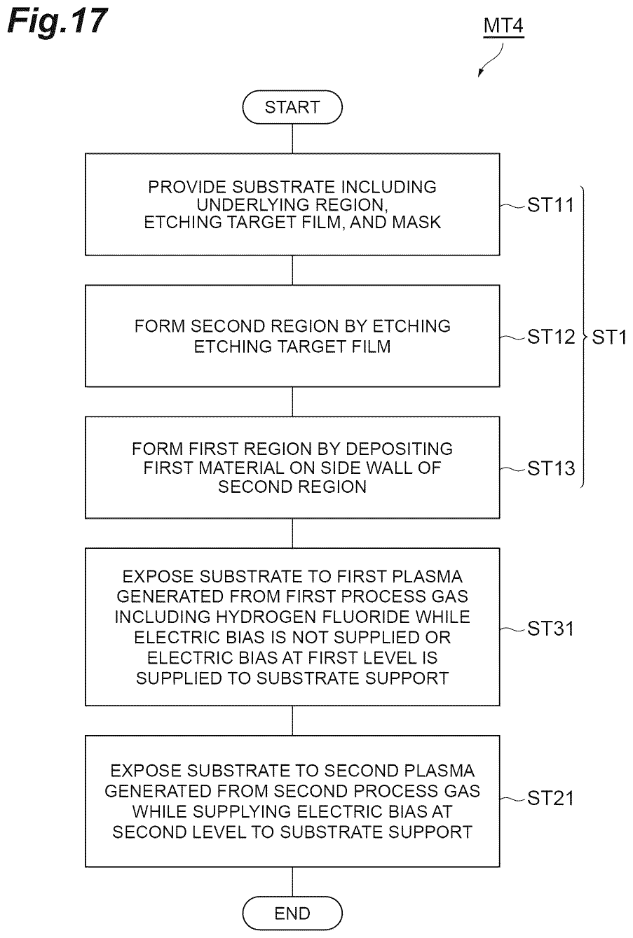

FIG. 17 is a flowchart illustrating an etching method according to an example embodiment. The etching method MT4 illustrated in FIG. 17 (hereinafter, referred to as “method MT4”) may be performed by the plasma processing apparatus 1 of the above-described embodiment. The method MT4 may be applied to the substrate W of FIG. 12.

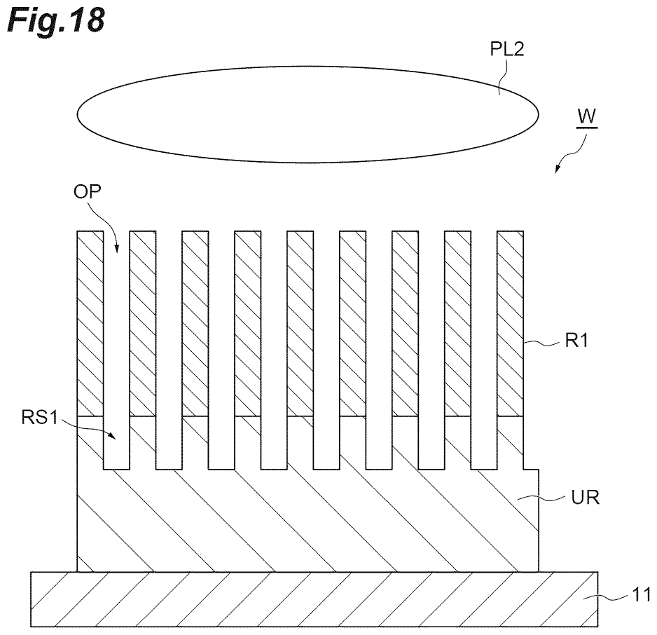

In the following, the method MT4 will be described with reference to FIGS. 13, 17, and 18 by using, as an example, the case where the method MT4 is applied to the substrate W of FIG. 12 by using the plasma processing apparatus 1 in the above-described embodiment. FIG. 18 is a cross-sectional view illustrating a step of the etching method according to an example embodiment. In a case where the plasma processing apparatus 1 is used, the method MT4 may be performed in the plasma processing apparatus 1 in a manner that the controller 2 controls each unit of the plasma processing apparatus 1. In the method MT3, as illustrated in FIG. 2, the substrate W on a substrate support 11 disposed in a plasma processing chamber 10 is processed.

As illustrated in FIG. 17, the method MT4 may include Step ST1, Step ST31, and Step ST21. Step ST1, Step ST31, and Step ST21 may be executed in order. Step ST31 may be performed after Step ST21. Step ST1 may include Step ST11 to Step ST13. Step ST1 may be performed in the same manner as Step ST1 of the method MT3.

### Step ST31

Step ST31 may be performed in the same manner as Step ST3. In Step ST31, as illustrated in FIG. 13, the substrate W is exposed to first plasma PL1 generated from the first process gas including hydrogen fluoride gas without supplying the electric bias to the substrate support 11 or while supplying the electric bias at a first level to the substrate support 11. Accordingly, the second region R2 is etched. The second region R2 is selectively etched with respect to the first region R1. The supply of the first process gas may be stopped at the end of Step ST31.

In a case where the electric bias is bias RF power, the level of the electric bias is a power level (effective value) of the bias RF power. In a case where the electric bias is bias DC power, the bias DC power may include a voltage pulse. In this case, the level of the electric bias is an absolute value of a negative voltage level of the voltage pulse.

### Step ST21

Step ST21 may be performed in the same manner as Step ST2. In Step ST21, as illustrated in FIG. 18, the substrate W is exposed to the second plasma PL2 generated from the second process gas while supplying the electric bias at a second level to the substrate support 11. The second level is higher than the first level that may be supplied to the substrate support 11 in Step ST31. The second process gas may be identical to or different from the first process gas in Step ST31. In Step ST21, the underlying region UR may be etched. A recess RS1 is formed in the underlying region UR by etching. The recess RS1 corresponds to the opening OP of the first region R1. The supply of the second process gas may be stopped at the end of Step ST21.

According to the method MT4, the etching of the first region R1 is suppressed in Step ST31, as compared with a case where a high level of electric bias is supplied to the substrate support 11. As a result, an etching selectivity of the second region R2 to the first region R1 can be improved.

Step ST31 of the method MT4 may be performed in Step ST3 of the method MT1 to the method MT3. That is, in Step ST3 of the method MT1 to the method MT3, the electric bias at the first level may be supplied to the substrate support 11. In this case, Step ST21 of the method MT4 may be performed in Step ST2 of the method MT1. That is, in Step ST2 of the method MT1, the electric bias at the second level may be supplied to the substrate support 11.

Although the various example embodiments have been described above, various additions, omissions, substitutions, and changes may be made without being limited to the example embodiments described above. Other embodiments can be formed by combining elements in different embodiments.

Here, the various example embodiments included in the present disclosure are described in [E1] to [E20] below.

### E1

An etching method comprising:
(a) providing a substrate on a substrate support in a chamber, the substrate including a first region and a second region, the first region including a first material including at least one selected from the group consisting of silicon oxide and carbon, and the second region including a second material different from the first material; and
(b) exposing the substrate to first plasma generated from a first process gas including hydrogen fluoride without supplying electric bias to the substrate support.

According to the above-described etching method [E1], in (b), the etching of the first region is suppressed. As a result, the etching selectivity of the second region to the first region can be improved.

### E2

The etching method according to [E1],
wherein the first region is a region on the second region and has at least one opening.

### E3

The etching method according to [E1] or [E2],
wherein, in the (b), a temperature of the substrate support is 10° C. to 150° C.

### E4

The etching method according to any one of [E1] to [E3], further comprising:
(c) exposing the substrate to second plasma generated from a second process gas different from the first process gas while supplying the electric bias to the substrate support,
wherein the second region is etched by repeating the (b) and the (c).

### E5

The etching method according to [E4],
wherein a duration of the (b) is shorter than a duration of the (c).

### E6

The etching method according to any one of [E1] to [E5],
wherein a duration of the (b) is 0.1 to 100 seconds.

### E7

The etching method according to any one of [E1] to [E6],
wherein a duration of the (c) is 0.1 to 100 seconds.

### E8

The etching method according to any one of [E1] to [E7],
wherein in the (b), radio frequency power is not supplied to the substrate support.

### E9

The etching method according to any one of [E1] to [E8],
wherein the second material includes at least one selected from the group consisting of silicon oxide, silicon nitride, silicon oxynitride, polysilicon, a metal, and carbon.

### E10

The etching method according to [E4] or any one of [E5] to [E9] depending on [E4],
wherein the second process gas includes a fluorocarbon gas.

### E11

The etching method according to any one of [E1] to [E10],
wherein the first process gas further includes an inert gas.

### E12

The etching method according to any one of [E1] to [E11],
wherein the second material includes at least one selected from the group consisting of silicon nitride, silicon oxynitride, polysilicon, and a metal.

### E13

The etching method according to any one of [E1] to [E12],
wherein the second material includes at least one metal selected from the group consisting of tungsten, molybdenum, and titanium.

### E14

The etching method according to any one of [E1] to [E13],
wherein the substrate further includes an underlying region,
the first region and the second region are regions on the underlying region,
at least a top of each of the first region and the second region is exposed, and
the second region is adjacent to the first region.

### E15

The etching method according to [E14],
wherein the (a) includes
   (a1) providing the substrate including the underlying region, an etching target film on the underlying region, and a mask on the etching target film, the etching target film including the second material and the mask including at least one opening,
   (a2) forming the second region by etching the etching target film through the at least one opening, and
   (a3) forming the first region by depositing the first material on a side wall of the second region.

### E16

The etching method according to any one of [E1] to [E15],
wherein, in the (b), the second region is selectively etched with respect to the first region.

### E17

An etching method comprising:
(a) providing a substrate on a substrate support in a chamber, the substrate including a first region and a second region, the first region including a first material including at least one selected from the group consisting of silicon oxide and carbon, and the second region including a second material different from the first material;
(b) exposing the substrate to first plasma generated from a first process gas including hydrogen fluoride without supplying electric bias to the substrate support or while supplying electric bias at a first level to the substrate support; and
(c) exposing the substrate to second plasma generated from a second process gas identical to or different from the first process gas while supplying electric bias at a second level that is higher than the first level to the substrate support.

### E18

The etching method according to [E17],
wherein the first region is a region on the second region and has at least one opening, and
the second region is etched by repeating the (b) and the (c).

### E19

The etching method according to [E17],
wherein the substrate further includes an underlying region,
the first region and the second region are regions on the underlying region,
at least a top of each of the first region and the second region is exposed, and
the second region is adjacent to the first region,
in the (b), the second region is selectively etched with respect to the first region, and
in the (c), the underlying region is etched.

### E20

A plasma processing apparatus comprising:
a chamber;
a substrate support for supporting a substrate in the chamber, the substrate including a first region and a second region, the first region including a first material including at least one selected from the group consisting of silicon oxide and carbon, and the second region including a second material different from the first material;
a gas supply configured to supply a first process gas including hydrogen fluoride to the chamber;
a plasma generator configured to generate first plasma from the first process gas in the chamber; and
a circuitry configured to control the gas supply and the plasma generator to execute (b) exposing the substrate to the first plasma without supplying electric bias to the substrate support.

From the foregoing description, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An etching method comprising:
providing a substrate on a substrate support in a chamber, the substrate including a first region and a second region, the first region including a first material including at least one selected from the group consisting of silicon oxide and carbon, and the second region including a second material different from the first material; and
exposing the substrate to first plasma generated from a first process gas including hydrogen fluoride without supplying electric bias to the substrate support.

2. The etching method according to claim 1, wherein
the first region is a region on the second region and has at least one opening.

3. The etching method according to claim 1, wherein
in the exposing the substrate to first plasma, a temperature of the substrate support is 10° C. to 150° C.

4. The etching method according to claim 2, further comprising:
exposing the substrate to second plasma generated from a second process gas different from the first process gas while supplying the electric bias to the substrate support,
wherein the second region is etched by repeating the exposing the substrate to first plasma and the exposing the substrate to second plasma.

5. The etching method according to claim 4, wherein
a duration of the exposing the substrate to first plasma is shorter than a duration of the exposing the substrate to second plasma.

6. The etching method according to claim 4, wherein
a duration of the exposing the substrate to first plasma is 0.1 to seconds.

7. The etching method according to claim 4, wherein
a duration of the exposing the substrate to second plasma is 0.1 to 100 seconds.

8. The etching method according to claim 4, wherein
in the exposing the substrate to first plasma, radio frequency power is not supplied to the substrate support.

9. The etching method according to claim 4, wherein
the second material includes at least one selected from the group consisting of silicon oxide, silicon nitride, silicon oxynitride, polysilicon, a metal, and carbon.

10. The etching method according to claim 4, wherein
the second process gas includes a fluorocarbon gas.

11. The etching method according to claim 4, wherein
the first process gas further includes an inert gas.

12. The etching method according to claim 2, wherein
the second material includes at least one selected from the group consisting of silicon nitride, silicon oxynitride, polysilicon, and a metal.

13. The etching method according to claim 2, wherein
the second material includes at least one metal selected from the group consisting of tungsten, molybdenum, and titanium.

14. The etching method according to claim 1, wherein
the substrate further includes an underlying region,
the first region and the second region are regions on the underlying region,
at least a top of each of the first region and the second region is exposed, and
the second region is adjacent to the first region.

15. The etching method according to claim 14, wherein
the providing a substrate on a substrate support in a chamber includes
providing the substrate including the underlying region, an etching target film on the underlying region, and a mask on the etching target film, the etching target film including the second material and the mask including at least one opening,
forming the second region by etching the etching target film through the at least one opening, and
forming the first region by depositing the first material on a side wall of the second region.

16. The etching method according to claim 14, wherein
in the exposing the substrate to first plasma, the second region is selectively etched with respect to the first region.

17. An etching method comprising:
providing a substrate on a substrate support in a chamber, the substrate including a first region and a second region, the first region including a first material including at least one selected from the group consisting of silicon oxide and carbon, and the second region including a second material different from the first material;
exposing the substrate to first plasma generated from a first process gas including hydrogen fluoride without supplying electric bias to the substrate support or while supplying electric bias at a first level to the substrate support; and
exposing the substrate to second plasma generated from a second process gas identical to or different from the first process gas while supplying electric bias at a second level that is higher than the first level to the substrate support.

18. The etching method according to claim 17, wherein
the first region is a region on the second region and has at least one opening, and
the second region is etched by repeating the exposing the substrate to first plasma and the exposing the substrate to second plasma.

19. The etching method according to claim 17, wherein
the substrate further includes an underlying region,
the first region and the second region are regions on the underlying region,
at least a top of each of the first region and the second region is exposed, and
the second region is adjacent to the first region,
in the exposing the substrate to first plasma, the second region is selectively etched with respect to the first region, and
in the exposing the substrate to second plasma, the underlying region is etched.

20. A plasma processing apparatus comprising:
a chamber;
a substrate support configured to support a substrate in the chamber, the substrate including a first region and a second region, the first region including a first material including at least one selected from the group consisting of silicon oxide and carbon, and the second region including a second material different from the first material;
a gas supply configured to supply a first process gas including hydrogen fluoride to the chamber;
a plasma generator configured to generate first plasma from the first process gas in the chamber; and
a circuitry configured to control the gas supply to supply the first process gas and the plasma generator to generate the first plasma from the first process gas and expose the substrate to the first plasma without supplying electric bias to the substrate support.
